(19) United States
(12) Patent Application Publication
(10) Pub. No.: US 2014/0151096 A1
(43) Pub. Date: Jun. 5, 2014

(54) LOW TEMPERATURE/HIGH TEMPERATURE SOLDER HYBRID SOLDER INTERCONNECTS

(71) Applicants: Hongjin Jiang, Chandler, AZ (US); Patrick N. Stover, Chandler, AZ (US); Arun Kumar C. Nallani, Chandler, AZ (US); Rajen Sidhu, Chandler, AZ (US); Ameya Limaye, Chandler, AZ (US)

(72) Inventors: Hongjin Jiang, Chandler, AZ (US); Patrick N. Stover, Chandler, AZ (US); Arun Kumar C. Nallani, Chandler, AZ (US); Rajen Sidhu, Chandler, AZ (US); Ameya Limaye, Chandler, AZ (US)

(21) Appl. No.: 13/693,403

(22) Filed: Dec. 4, 2012

(51) Int. Cl. H05K 1/11; H05K 3/34; H05K 1/09

(52) U.S. Cl. CPC H05K 1/111; H05K 1/09; H05K 3/3494
USPC 174/257; 174/250; 29/840

(57) ABSTRACT

Embodiments of the present description relate to the field of fabricating microelectronic structures, wherein a microelectronic package may be attached to a microelectronic substrate with a hybrid solder interconnect. The hybrid solder interconnect may comprise a homogenous mixture of low temperature solder and a high temperature solder extending between at least one bond pad on a microelectronic package and at least one bond pad on a microelectronic substrate, wherein the relatively low reflow temperature used during the formation of the hybrid solder interconnect may prevent solder defects caused by warpage which may occur during the attachment of the microelectronic package to the microelectronic substrate.

### BACKGROUND

Embodiments of the present description generally relate to the field of microelectronic structures and, more particularly, to low melting point temperature solder in conjunction with a high melting point temperature solder to form a hybrid solder interconnect.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 illustrates a side cross-sectional view of a microelectronic package mounted on a microelectronic substrate, as known in the art.

FIGS. 2-4 illustrate side cross-sectional views of mounting a microelectronic package on a microelectronic substrate, as known in the art.

FIGS. 5-7 illustrate side cross-sectional views of mounting a microelectronic package on a microelectronic substrate, according to an embodiment of the present description.

FIG. 8 illustrates a side cross-sectional view of mounting a microelectronic package on a microelectronic substrate, according to another embodiment of the present description.

FIGS. 9 and 10 illustrate side cross-sectional views of mounting a microelectronic package on a microelectronic substrate, according to still another embodiment of the present description.

FIG. 11 illustrates a side cross-sectional view of a hybrid solder structure, according to still another embodiment of the present description.

FIG. 12 is a micrograph of the hybrid solder structure of FIG. 11, according to still another embodiment of the present description.

FIG. 13 illustrates a side cross-sectional view of a hybrid solder structure, according to still another embodiment of the present description.

FIG. 14 illustrates a side cross-sectional view of a hybrid solder interconnect, according to an embodiment of the present description.

FIG. 15 is a flow chart of a process of mounting a microelectronic package on a microelectronic substrate, according to an embodiment of the present description.

FIG. 16 is a flow chart of a process of mounting a microelectronic package on a microelectronic substrate, according to an embodiment of the present description.

FIG. 17 is a flow chart of a process of mounting a microelectronic package on a microelectronic substrate, according to an embodiment of the present description.

FIG. 18 illustrates an electronic system, according to one embodiment of the present description.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present invention. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

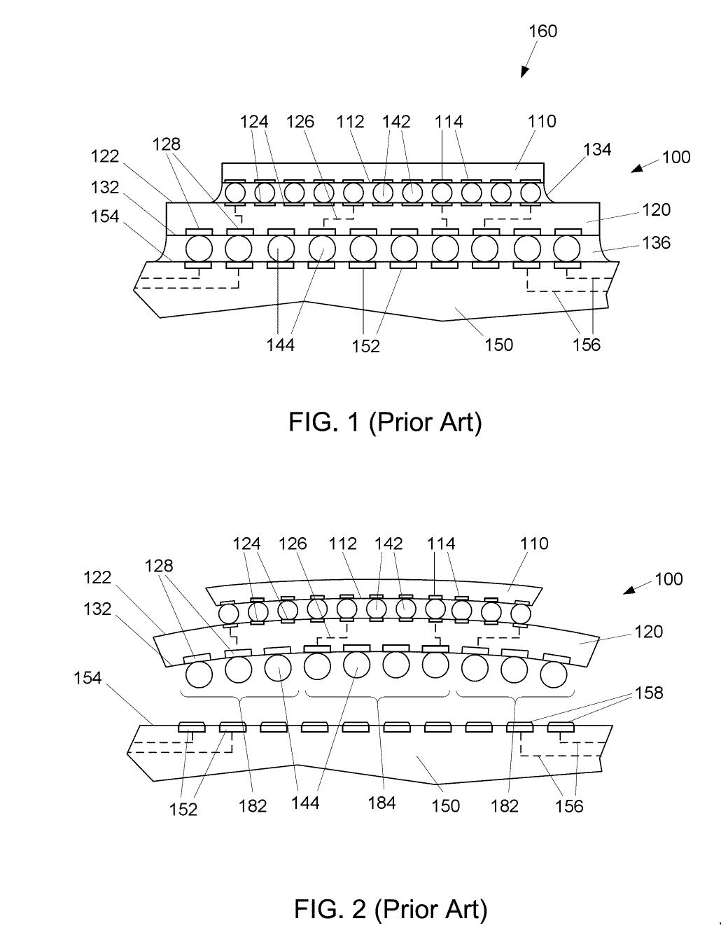

In the production of microelectronic systems, microelectronic packages are generally mounted on microelectronic substrates, which provide electrical communication routes between the microelectronic packages and external components. As shown in FIG. 1, a microelectronic package 100 may comprise a microelectronic device 110, such as a microprocessor, a chipset, a graphics device, a wireless device, a memory device, an application specific integrated circuit, or the like, attached to a first surface 122 of a microelectronic interposer 120 through a plurality of interconnects 142, such as reflowable solder bumps or balls, in a configuration generally known as a flip-chip or controlled collapse chip connection (“C4”) configuration. The device-to-interposer interconnects 142 may extend from bond pads 114 on an active surface 112 of the microelectronic device 110 and bond pads 124 on the microelectronic interposer first surface 122. The microelectronic device bond pads 114 may be in electrical communication with integrated circuitry (not shown) within the microelectronic device 110. The microelectronic interposer 120 may include at least one conductive route 126 extending there through from at least one microelectronic interposer first surface bond pad 124 and at least one bond pad 128 on a second surface 132 of the microelectronic interposer 120. The microelectronic interposer 120 may reroute a fine pitch (center-to-center distance between the microelectronic device bond pads 114) of the microelectronic device bond pads 114 to a relatively wider pitch of the microelectronic interposer second surface bond pads 128. A first underfill material 134, such as an epoxy, may be disposed between the microelectronic device 110 and the microelectronic interposer 120, which may increase structural stability and prevent potential contaminants from affecting the device-to-interposer interconnects 142.

The microelectronic package 100 may be attached to a microelectronic substrate 150, such as printed circuit board, a motherboard, and the like, through a plurality of interconnects 144, such as reflowable solder bumps or balls, to form a microelectronic system 160. The interposer-to-substrate interconnects 144 may extend between the microelectronic interposer second surface bond pads 128 and substantially mirror-image bond pads 152 on an attachment surface 154 of the microelectronic substrate 150. The microelectronic substrate bond pads 152 may be in electrical communication with conductive routes (shown as dashed lines 156) within the microelectronic substrate 150. The microelectronic substrate conductive routes 156 may provide electrical communication routes to external components (not shown). A second underfill material 136, such as an epoxy, may be disposed between the microelectronic interposer 120 and the microelectronic substrate 150, which may increase structural stability and prevent potential contaminants from affecting the interposer-to-substrate interconnects 144.

Both the microelectronic interposer 120 and the microelectronic substrate 150 may be primarily composed of any appropriate material, including, but not limited to, bismaleimine triazine resin, fire retardant grade 4 material, polyimide materials, glass reinforced epoxy matrix material, and the like, as well as laminates or multiple layers thereof. The microelectronic interposer conductive routes 126 and the microelectronic substrate conductive routes 156 may be composed of any conductive material, including but not limited to metals, such as copper and aluminum, and alloys thereof. As will be understood to those skilled in the art, microelectronic interposer conductive routes 126 and the microelectronic substrate conductive routes 156 may be formed as a plurality of conductive traces (not shown) formed on layers of dielectric material (constituting the layers of the microelectronic substrate material), which are connected by conductive vias (not shown).

The interposer-to-substrate interconnects 144 can be made of any appropriate material, including, but not limited to, solders materials. The solder materials may be any appropriate material, including but not limited to, lead/tin alloys and high tin content alloys (e.g. 90% or more tin), and similar alloys. When the microelectronic device 110 is attached to the microelectronic substrate 150 with interposer-to-substrate interconnects 144 made of solder, the solder is reflowed, either by heat, pressure, and/or sonic energy to secure the solder between the microelectronic interposer second surface bond pads 128 and the microelectronic substrate bond pads 152.

In such microelectronic systems, as shown in FIG. 2, a microelectronic package 100 usually has a convex-shaped warpage (i.e. interposer-to-substrate interconnects at edge portions 182 of microelectronic package 100 would be closer to the microelectronic substrate attachment surface 154 than interposer-to-substrate interconnects 144 at a center portion 184 of the microelectronic package 100) at room temperature (about 25 degrees Celsius). This convex-shaped warpage results from CTE (coefficient of thermal expansion) mismatch between the predominant material(s) of the microelectronic device 110 (such as silicon) and the predominant material(s) of the microelectronic interposer 120 (such as organic materials).

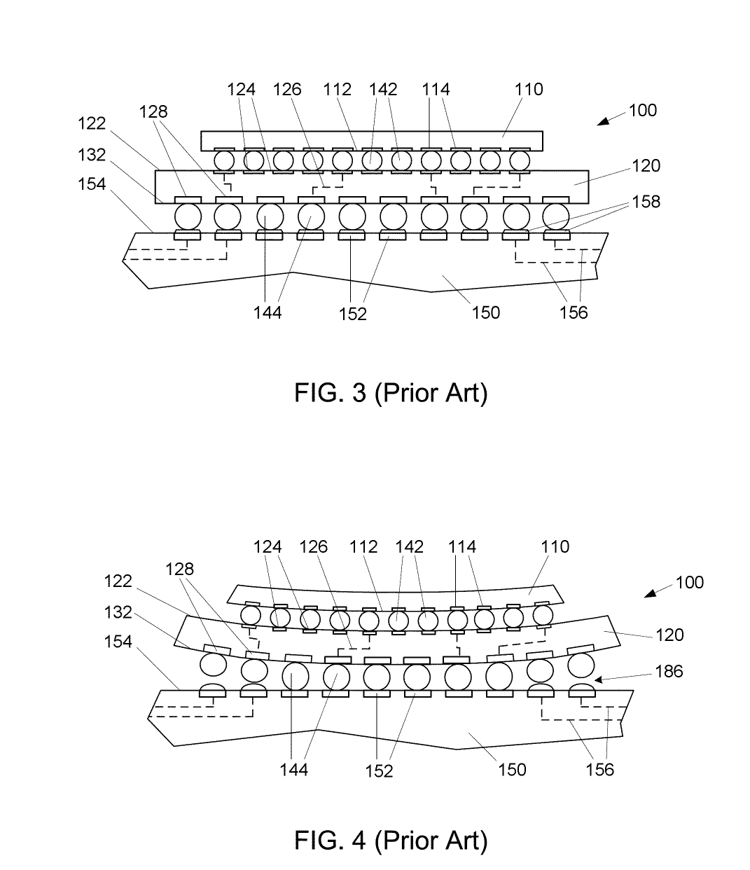

As shown in FIG. 3, during an attachment process, the microelectronic package 110 and the microelectronic substrate 150 are heated, wherein the warpage begins to decrease, such that the microelectronic package 110 may be substantially flat or substantially planar or parallel relative to the microelectronic substrate 150 at a temperature range between about 150 and 180 degrees Celsius. As will be understood to those skilled in that art, the temperature at which the microelectronic package 110 is substantially planar will be dependent upon the microelectronic package 110 design and materials used. Also, as shown in FIGS. 2 and 3, the microelectronic substrate 150 may also include a solder paste 158, which may have a reflow temperature which is substantially the same as the reflow temperature of the interposer-to-substrate interconnects 144, may be disposed on the microelectronic substrate bond pads 152.

As shown in FIG. 4, as the microelectronic package 100 and the microelectronic substrate 150 are further heated to reach a reflow temperature of the interposer-to-substrate interconnects 144, generally greater than 180 degree Celsius, the warpage of the microelectronic package 100 may change to a concave shape (i.e. interposer-to-substrate interconnects 144 at edge portions 182 (see FIG. 2) of microelectronic package 100 would be further away from the microelectronic substrate attachment surface 154 than interposer-to-substrate interconnects 144 at a center portion 184 (see FIG. 2) of the microelectronic package 100). The interposer-to-substrate interconnect reflow temperature is a temperature to which interposer-to-substrate interconnects 144 are heated to attach to the bond pads between the microelectronic device 110 and the microelectronic interposer 150. Such concave-shaped warpage may result in interconnect joint opens 186 (e.g. head and pillow, non-contact open or non-wet open defects, as know in the art), as shown in FIG. 4, and/or interconnect bridging during the reflow process.

Embodiments of the present description relate to the field of fabricating microelectronic structures, wherein a microelectronic package may be attached to a microelectronic substrate with a hybrid solder interconnect. The hybrid solder interconnect may comprise a homogenous mixture of low temperature solder and a high temperature solder extending between at least one bond pad on a microelectronic package and at least one bond pad on a microelectronic substrate, wherein the relatively low reflow temperature used during the formation of the hybrid solder interconnect may prevent solder defects caused by warpage which may occur during the attachment of the microelectronic package to the microelectronic substrate.

For the purposes of the present description, a high temperature solder material or ball/bump is defined to be a solder material having a melting or reflow temperature equal to greater than 200 degrees Celsius and a low temperature solder material is defined to be a solder material having a melting or reflow temperature less than 200 degrees Celsius.

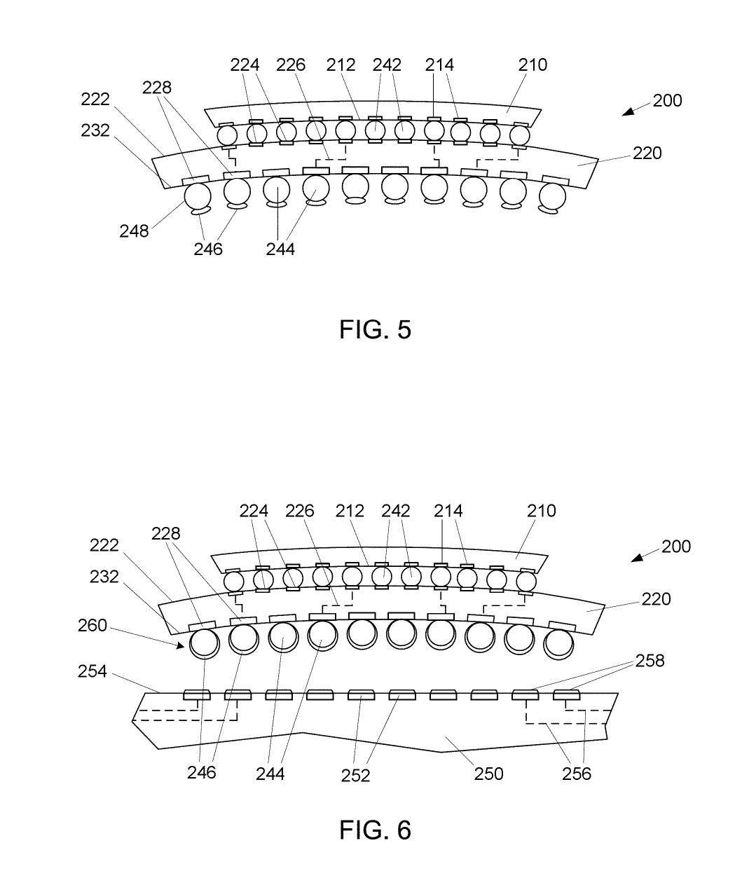

FIGS. 5-8 illustrate a method of fabricating a microelectronic structure 270 according to one embodiment of the present description. As shown in FIG. 5, a microelectronic package 200 (similar to microelectronic package 100 of FIGS. 1-4) may be formed, including a microelectronic device 210, such as a microprocessor, a chipset, a graphics device, a wireless device, a memory device, an application specific integrated circuit, or the like, attached to a first surface 222 of a microelectronic interposer 220 through a plurality of interconnects 242, such as reflowable solder bumps or balls, in a configuration generally known as a flip-chip or controlled collapse chip connection (“C4”) configuration. The device-to-interposer interconnects 242 may extend from bond pads 214 on an active surface 212 of the microelectronic device 210 and bond pads 224 on the microelectronic interposer first surface 222. The microelectronic device bond pads 214 may be in electrical communication with integrated circuitry (not shown) within the microelectronic device 210. The microelectronic interposer 220 may include at least one conductive route 226 extending there through from at least one microelectronic interposer first surface bond pad 224 and at least one microelectronic package bond pad 228 on a second surface 232 of the microelectronic interposer 220. The microelectronic interposer 220 may reroute a fine pitch (center-to-center distance between the microelectronic device bond pads 214) of the microelectronic device bond pads 214 to a relatively wider pitch of the microelectronic package bond pads 228. As previously discussed, the microelectronic package 200 has a substantially convex-shaped warpage at room temperature (about 25 degrees Celsius).

The microelectronic package 200 may further include at least one high temperature solder ball or bump 244 attached to a respective microelectronic package pond pad 228. The high temperature solder ball 244 may be made of any appropriate high temperature solder material, including but not limited to lead-free solder materials, such as tin/silver/copper alloys.

In one embodiment of the present description, the lead-free solder material may comprise an alloy of about 95.5% tin (Sn), 4% silver (Ag), and 0.5% copper, known as SAC405. In another embodiment of the present description, the lead-free solder material may comprise an alloy of about 96.5% tin (Sn), 3% silver (Ag), and 0.5% copper, known as SAC305. Other solder materials that may be used for the high temperature solder material 244, may include but is not limited to bismuth/silver alloys, tin/silver/antimony alloys, tin (5%-10%)/silver alloys, tin (2%-8%)/copper alloys, in accordance with various embodiments. In one embodiment of the present description, the high temperature solder balls 244 may have a reflow temperature of greater than about 200 degrees Celsius, and may be greater than about 215 degrees Celsius. The high temperature solder balls 244 may be formed or attached by techniques which are well known in the art.

As further shown in FIG. 5, a low temperature solder material 246 may be disposed on each of the high temperature solder balls 244. The low temperature solder material 246 may include any appropriate low temperature solder material, including but not limited to tin/bismuth/copper/nickel alloys and tin/bismuth/copper/antimony alloys. In another embodiment, the low temperature solder material 246 may be an off-eutectic (high tin) tin/bismuth/copper alloy, which may have a reflow temperature of less than about 175 degrees Celsius, as such alloys, particularly those having a tin concentration of between about 42% and 60% (having a liquidus range or between about 138 and 170 degree Celsius). In one embodiment of the present description, the low temperature solder material 246 may have a reflow temperature of less than about 200 degrees Celsius, and may be less than about 170 degrees Celsius. The low temperature solder material 246 may be disposed by any technique known in the art, including, but not limited to, printing techniques.

The microelectronic package 200 may be heated to the reflow temperature of the low temperature solder material 246, such that the low temperature solder material 246 substantially coats a majority of an exposed surface 248 (e.g. the surface not attached to the microelectronic package bond pad 228—see FIG. 5) of the high temperature solder ball 244 thereby forming a hybrid solder structure 260, as illustrated in FIG. 6.

As further shown in FIG. 6, the microelectronic package 200 may be positioned with regard to a microelectronic substrate 250, such as printed circuit board, a motherboard, and the like, wherein the high temperature solder balls 244 are aligned with substantially mirror-image bond pads 252 on an attachment surface 254 of the microelectronic substrate 250. The microelectronic substrate bond pads 252 may be in electrical communication with conductive routes (shown as dashed lines 256) within the microelectronic substrate 250. The microelectronic substrate conductive routes 256 may provide electrical communication routes to external components (not shown). Additionally, a solder paste 258 may be disposed on the microelectronic substrate bond pads 252 to assist in the attachment process, as will be understood to those skilled in the art. The solder paste 258 may include the material of the low temperature solder material 246 or the high temperature solder balls 244.

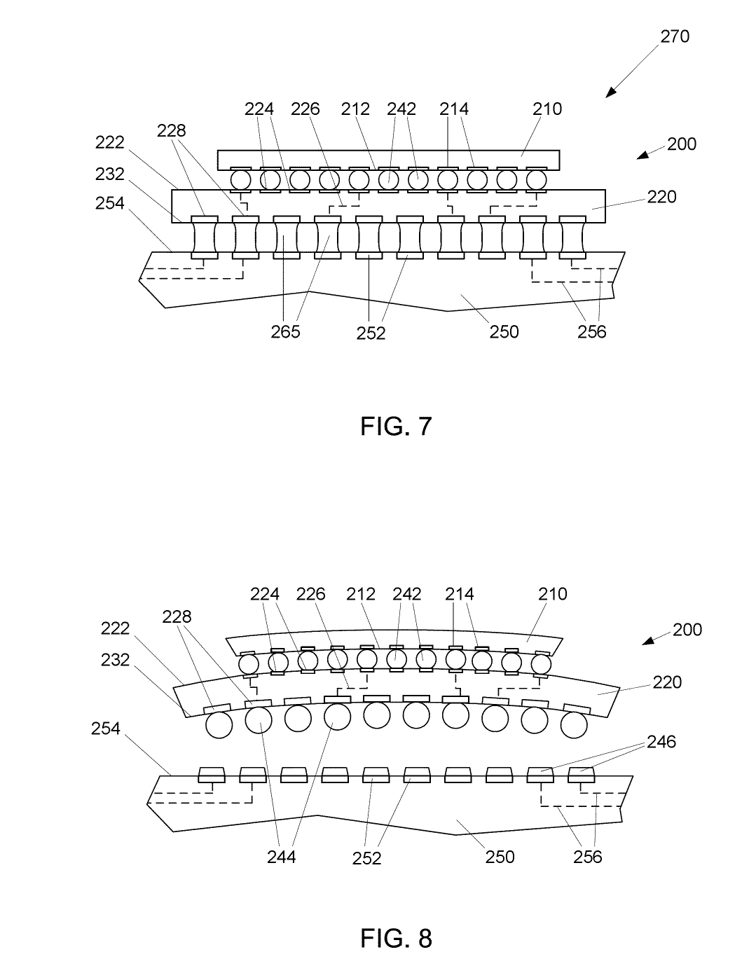

As shown in FIG. 7, the microelectronic package 200 may be brought into contact with the microelectronic substrate 250 and heated to the reflow temperature of the hybrid solder structures 260. The hybrid solder structures 260 may have a suppressed melting point and solidification point compared to the high temperature solder balls 244 alone. Thus, the hybrid solder structures 260 may start to melt and collapse at a temperature lower than that of the high temperature solder balls 244 alone (and before the solder paste 258, if used) to form a hybrid solder interconnects 265 between the microelectronic package bond pads 228 and the microelectronic substrate bond pads 252, thereby forming the microelectronic structure 270. In one embodiment, the resulting hybrid solder interconnects 265 may be a substantially homogeneous structure, wherein the low temperature solder material 246 is substantially evenly distributed with material of the high temperature solder ball 244. Furthermore, due to the lower solidification point of the hybrid solder interconnects 265 relative to the high temperature solder balls 244 material alone, the formation of the hybrid solder interconnects 265 may occur at a lower temperature with lower warpage (previously discussed), thereby preventing interconnect joint opens (see element 160 of FIG. 4) or interconnect bridging, as previously discussed. Furthermore, if the solder paste 258 of FIG. 6 is used, it may be subsumed into the hybrid solder interconnects 265.

In another embodiment of the present description, as shown in FIG. 8, the low temperature material 246 may be patterned on each of the microelectronic substrate bond pads 252, such as by screen printing, stenciling, and the like. The microelectronic package 200 may be brought into contact with the microelectronic substrate 250 and heated, thereby forming the hybrid solder interconnects 265, as discussed and shown in FIG. 7. The mechanisms for the formation of the hybrid solder interconnects 265 may be substantially the same as discussed with regard to FIGS. 5-7. Additionally, the low temperature solder material 246 on the microelectronic substrate 254 is a molten state at a lower temperature and has a strong wetting force, such that it can “stretch” to extend between each of the high temperature solder balls 244 and their respective microelectronic substrate bond pads 252, thereby preventing interconnect joint opens, as will be understood to those skilled in the art.

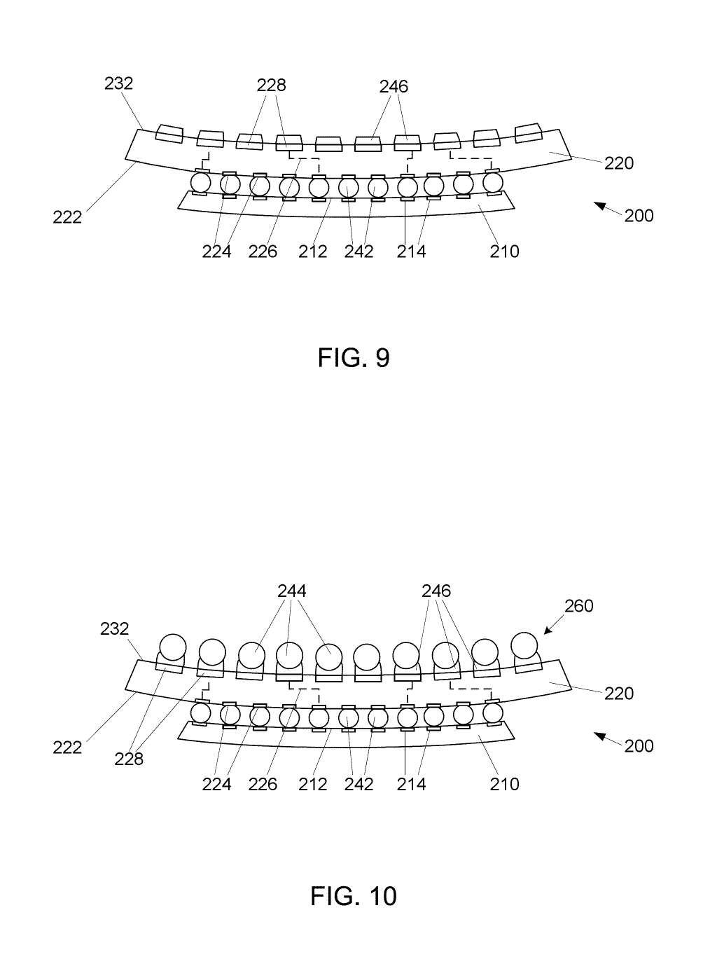

In still another embodiment of the present description, a microelectronic structure 280 may be formed with the low temperature solder material 244 between the high temperature solder ball 244 and the microelectronic package bond pad 228. Prior to the attachment of the high temperature solder balls 244 to the microelectronic package 200, the microelectronic package 200 may be flipped such that the microelectronic package bond pads 228 face upward (e.g. substantially opposite to the direction of gravitational pull) and a low temperature solder material 246 patterned on the microelectronic package bond pads 228, as shown in FIG. 9. The low temperature solder material 246 may be patterned by any technique known in the art, including but not limited to screen printing and stenciling.

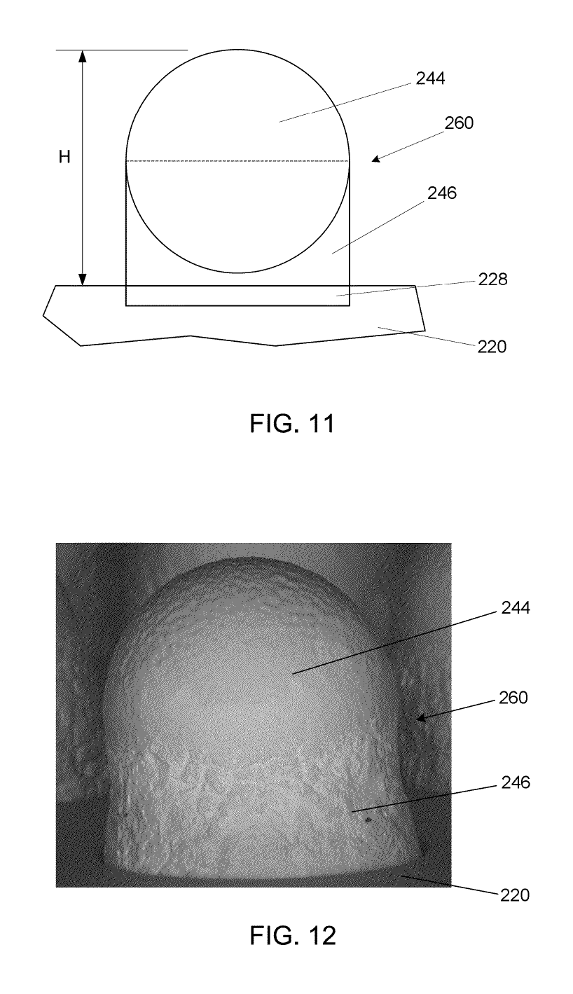

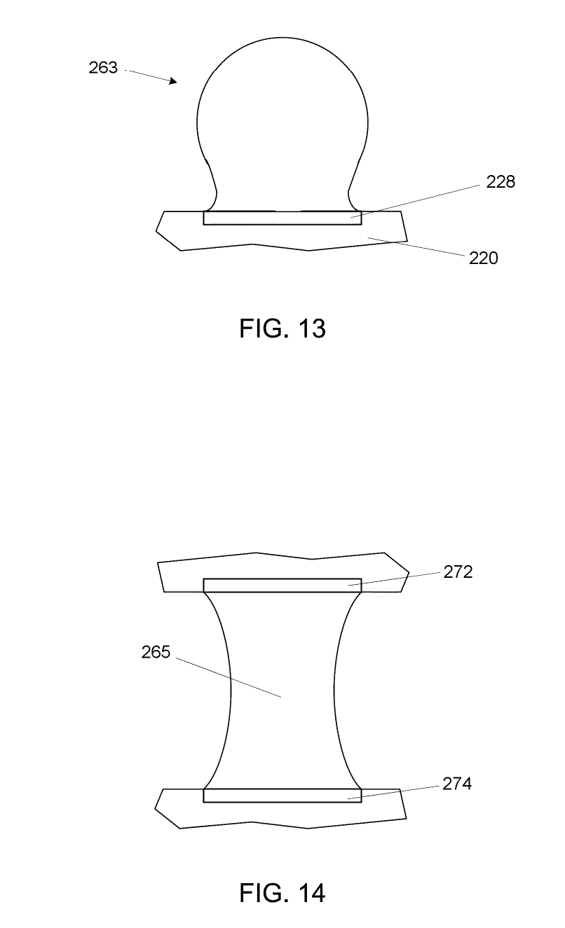

As shown in FIG. 10, the high temperature solder balls 244 may be placed on each respective microelectronic package bond pads 228. The low temperature solder material 246 may then be reflowed to secure the high temperature solder balls 244 without reflowing the high temperature solder balls 244 to form hybrid solder structures 260, as shown in FIGS. 11 and 12. In another embodiment, structure may be heat to the reflow temperature of the high temperature solder balls 244 to form a homogenized hybrid solder structure 263, as shown in FIG. 13. Due to the low temperature solder material 246 having a reflow temperature lower than the high temperature solder balls 244, the low temperature solder material 246 may provide higher wetting or holding force to the high temperature solder balls 244, which may result in better self-alignment during reflow to provide the high temperature solder ball 244 attachment process and increase yield, as will be understood to those skilled in the art.

Additionally, the process and structure shown in FIGS. 10-12 may result in the hybrid solder structure 260 having a height H (see FIGS. 11) that may be greater than would result from known processes, without increasing the overall solder volume of the hybrid solder structure 260. Thus, the hybrid solder structures 260 may be used in applications, such as through-mold interconnects, which require a greater structure height, but cannot increase the solder volume of the structure due to tight pitch constraints, as will be understood to those skilled in the art.

The structure of FIG. 12 may be flipped, brought into contact with the microelectronic substrate bond pads, and heated to the reflow temperature of the high temperature solder ball 244 to form the hybrid solder interconnect 265 and thereby forming the microelectronic structure 270, as shown in FIG. 7. The mechanisms for the formation of the hybrid solder interconnects 265 may be substantially the same as discussed with regard to FIGS. 5-7.

FIG. 14 illustrates a single hybrid interconnect 265 extending between a first bond pad 272, which may be the microelectronic package bond pad 228 or the microelectronic substrate bond pad 252 (see previous figures), and a second bond pad 274, which be the other of the microelectronic package bond pad 228 or the microelectronic substrate bond pad 252 (see previous figures). Again, the reflow of the low temperature solder material 246 and the high temperature solder ball 244 may result in the hybrid interconnect 265 being a substantially homogeneous structure, wherein the low temperature solder material 246 is substantially evenly distributed with the high temperature solder ball 244. It is understood that the amount of low temperature solder material 246 used relative to the volume of the high temperature solder ball 244 will depend upon the materials used and the solder joint reliability requirements.

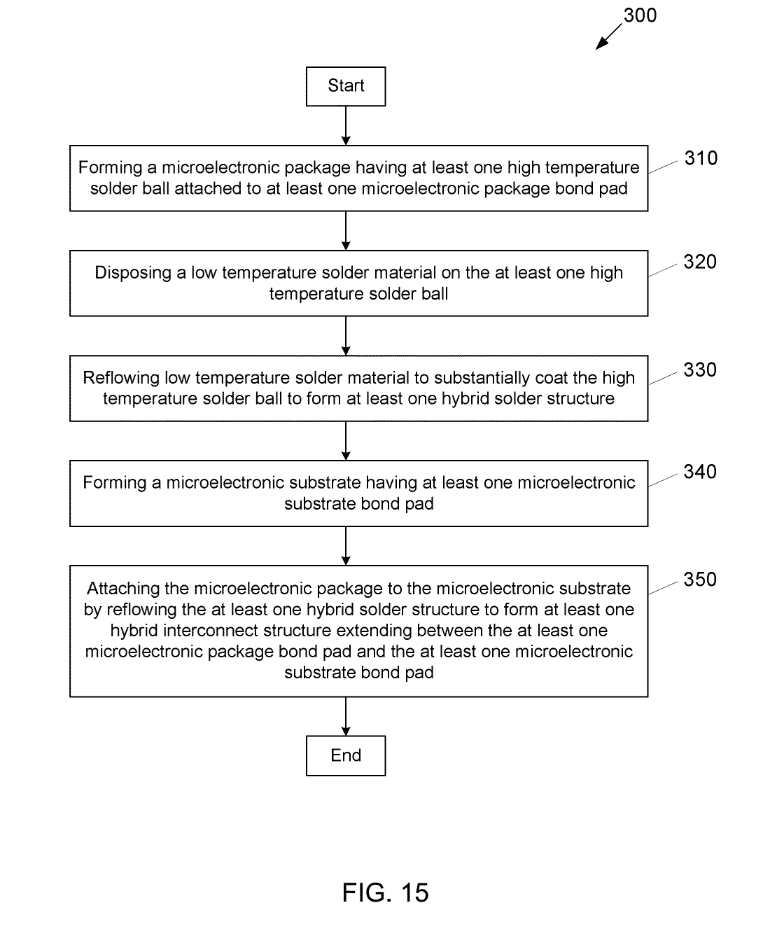

FIG. 15 is a flow chart of a process 300 of fabricating a microelectronic structure according to the various embodiments of the present description. As set forth in block 310, a microelectronic package may be formed having at least one high temperature solder ball attached to at least one microelectronic package bond pad. A low temperature solder material may be disposed on the at least one high temperature solder ball, as defined in block 320. As set forth in block 330, the low temperature solder material may be reflowed to substantially coat the each high temperature solder ball to form at least one hybrid solder structure. As defined in block 340, a microelectronic substrate may be formed having at least one microelectronic substrate bond pad. The microelectronic package may be attached to the microelectronic substrate by reflowing the at least one hybrid solder structure to form at least one hybrid interconnect extending between the at least one microelectronic package bond pad and the at least one microelectronic substrate bond pad, as set forth in block 350.

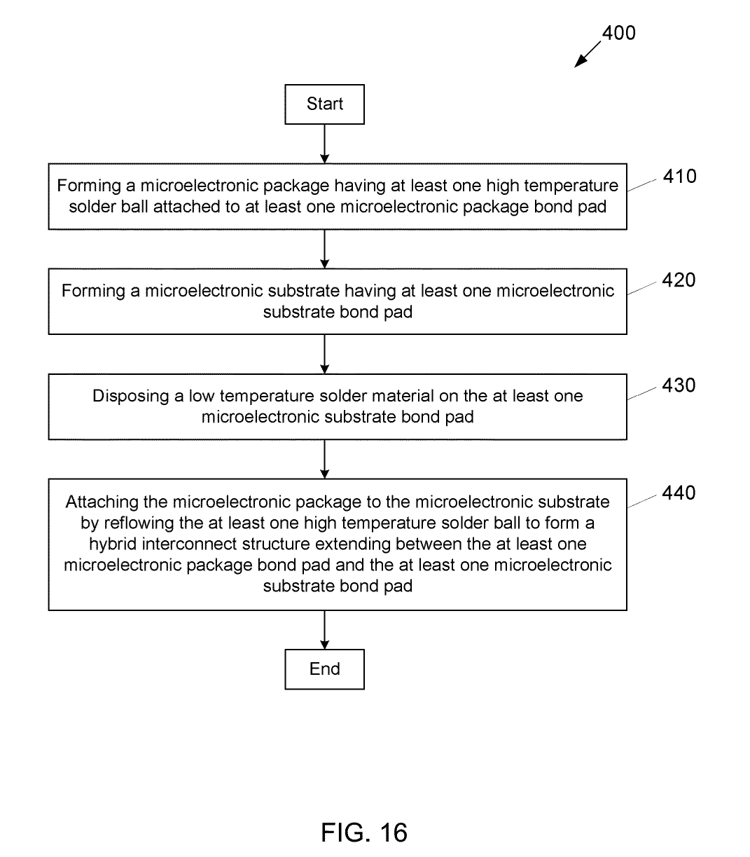

FIG. 16 is a flow chart of a process 400 of fabricating a microelectronic structure according to another embodiment of the present description. As set forth in block 410, a microelectronic package may be formed having at least one high temperature solder ball attached to at least one microelectronic package bond pad. As defined in block 420, a microelectronic substrate may be formed having at least one microelectronic substrate bond pad. A low temperature solder material may be disposed on the at least one microelectronic substrate bond pad, as defined in block 430. As set forth in block 440, the microelectronic package may be attached to the microelectronic substrate by reflowing the at least one high temperature solder ball to form a hybrid interconnect extending between the at least one microelectronic package bond pad and the at least one microelectronic substrate bond pad.

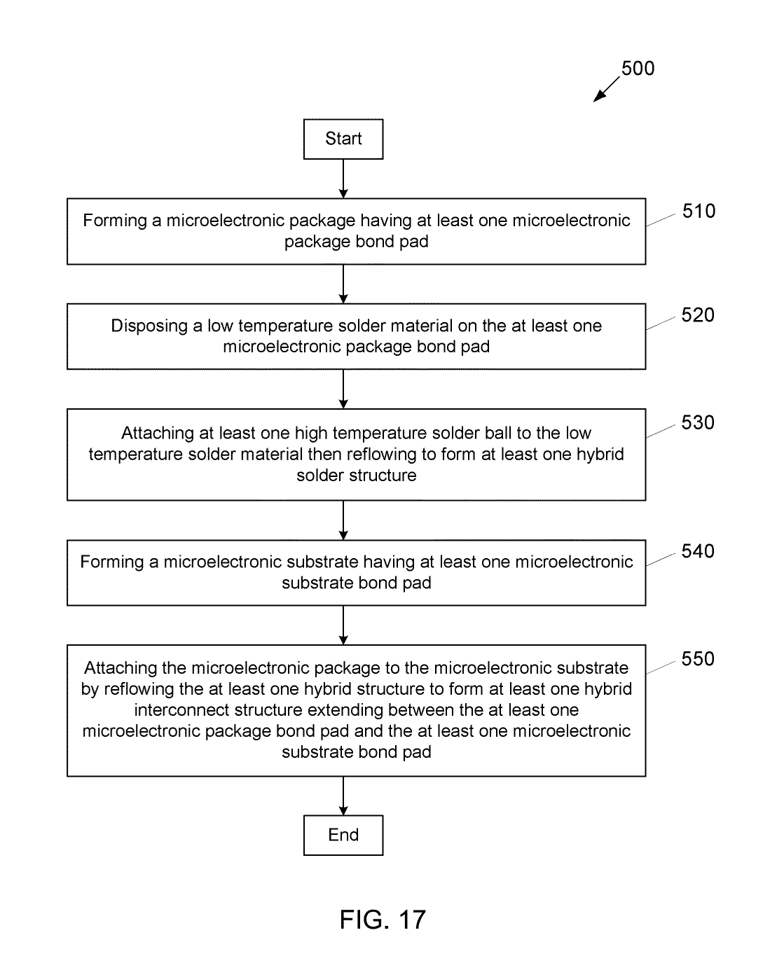

FIG. 17 is a flow chart of a process 500 of fabricating a microelectronic structure according to yet another embodiment of the present description. As set forth in block 510, a microelectronic package may be formed having at least one microelectronic package bond pad. A low temperature solder material may be disposed on the at least one microelectronic package bond pad, as defined in block 520. At least one high temperature solder ball may be attached to the low temperature solder and then reflowed to form at least one hybrid solder structure, as defined in block 530. A microelectronic substrate may be formed having at least one microelectronic substrate bond pad, as defined in block 540. As set forth in block 550, the microelectronic package may be attached to the microelectronic substrate by reflowing the at least one hybrid solder structure to form a hybrid solder interconnect extending between the at least one microelectronic package bond pad and the at least one microelectronic substrate bond pad.

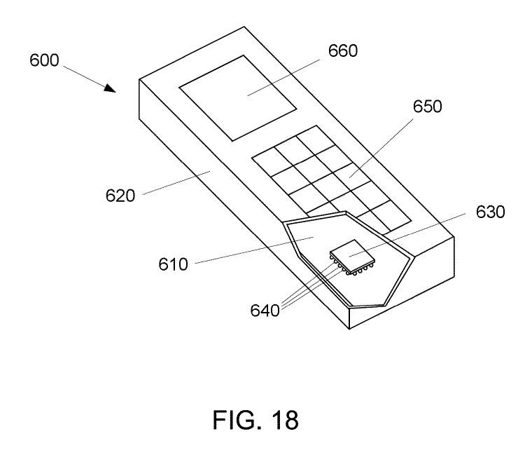

FIG. 18 illustrates an embodiment of an electronic system/device 600, such as a portable computer, a desktop computer, a mobile telephone, a digital camera, a digital music player, a web tablet/pad device, a personal digital assistant, a pager, an instant messaging device, or other devices. The electronic system/device 600 may be adapted to transmit and/or receive information wirelessly, such as through a wireless local area network (WLAN) system, a wireless personal area network (WPAN) system, and/or a cellular network. The electronic system/device 600 may include a microelectronic motherboard or substrate 610 disposed within a device housing 620. The microelectronic motherboard/substrate 610 may have various electronic components electrically coupled thereto including a microelectronic package 630 attached to the microelectronic motherboard/substrate 610 with a plurality of hybrid solder interconnects 640, as previously described. The microelectronic motherboard/substrate 610 may be attached to various peripheral devices including an input device 650, such as keypad, and a display device 660, such an LCD display. It is understood that the display device 660 may also function as the input device, if the display device 660 is touch sensitive.

It is understood that the subject matter of the present description is not necessarily limited to specific applications illustrated in FIGS. 1-18. The subject matter may be applied to other microelectronic device fabrication applications, as will be understood to those skilled in the art.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A hybrid solder structure, comprising:
a bond pad;
a high temperature solder ball; and
a low temperature solder material disposed between the bond pad and the high temperature solder ball.

2. The hybrid structure of claim 1, wherein the high temperature solder ball comprises a tin/silver/copper alloy.

3. The microelectronic structure of claim 2, wherein the tin/silver/copper alloy comprises an alloy of about 95.5% tin, about 4% silver, and about 0.5% copper.

4. The microelectronic structure of claim 1, wherein the low temperature solder material comprises a tin/bismuth/copper/nickel alloy.

5. The microelectronic structure of claim 1, wherein the low temperature solder material comprises a tin/bismuth/copper/antimony alloy.

6. The microelectronic structure of claim 1, wherein the bond pad is disposed on an attachment surface of the microelectronic package.

7. A hybrid solder structure, comprising:
a bond pad;
a high temperature solder ball attached to the bond pad; and
a low temperature solder material disposed on at least a portion of the high temperature solder ball not attached to the bond pad.

8. The hybrid structure of claim 7, wherein the high temperature solder ball comprises a tin/silver/copper alloy.

9. The microelectronic structure of claim 8, wherein the tin/silver/copper alloy comprises an alloy of about 95.5% tin, about 4% silver, and about 0.5% copper.

10. The microelectronic structure of claim 7, wherein the low temperature solder material comprises a tin/bismuth/copper/nickel alloy.

11. The microelectronic structure of claim 7, wherein the low temperature solder material comprises a tin/bismuth/copper/antimony alloy.

12. The microelectronic structure of claim 7, wherein the bond pad is disposed on an attachment surface of the microelectronic package.

13. A method of fabricating a microelectronic structure, comprising:
forming a microelectronic package having at least one high temperature solder ball attached to at least one microelectronic package bond pad;
disposing a low temperature solder material on the at least one high temperature solder ball;
forming a microelectronic substrate having at least one microelectronic substrate bond pad; and
attaching the microelectronic package to the microelectronic substrate by reflowing the at least one high temperature solder ball to form a hybrid solder interconnect extending between the at least one microelectronic package bond pad and the at least one microelectronic substrate bond pad.

14. The method of claim 13, further including reflowing the low temperature solder material to substantially coat the high temperature solder ball prior to attaching the microelectronic package to the microelectronic substrate.

15. The method of claim 13, wherein forming the microelectronic package having at least one high temperature solder ball attached to at least one microelectronic package bond pad comprises forming the microelectronic package having at least one high temperature solder ball comprising a tin/silver/copper alloy, attached to at least one microelectronic package bond pad.

16. The method of claim 15, wherein forming the microelectronic package having at least one high temperature solder ball, comprising a tin/silver/copper alloy, attached to at least one microelectronic package bond pad comprises forming the microelectronic package having at least one high temperature solder ball, comprising an alloy of about 95.5% tin, about 4% silver, and about 0.5% copper, attached to at least one microelectronic package bond pad.

17. The method of claim 13, wherein disposing a low temperature solder material on the at least one high temperature solder ball comprises disposing a low temperature solder material, comprising a tin/copper/nickel alloy, on the at least one high temperature solder ball.

18. The method of claim 13, wherein disposing a low temperature solder material on the at least one high temperature solder ball comprises disposing a low temperature solder material, comprising a tin/copper/antimony alloy, on the at least one high temperature solder ball.

19. A method of fabricating a microelectronic structure, comprising:
forming a microelectronic package having at least one high temperature solder ball attached to at least one microelectronic package bond pad;
forming a microelectronic substrate having at least one microelectronic substrate bond pad;
disposing a low temperature solder material on the at least one microelectronic substrate bond pad; and
attaching the microelectronic package to the microelectronic substrate by reflowing the at least one high temperature solder ball to form a hybrid solder interconnect extending between the at least one microelectronic package bond pad and the at least one microelectronic substrate bond pad.

20. The method of claim 19, wherein forming the microelectronic package having at least one high temperature solder ball attached to at least one microelectronic package bond pad comprises forming the microelectronic package having at least one high temperature solder ball comprising a tin/silver/copper alloy, attached to at least one microelectronic package bond pad.

21. The method of claim 20, wherein forming the microelectronic package having at least one high temperature solder ball, comprising a tin/silver/copper alloy, attached to at least one microelectronic package bond pad comprises forming the microelectronic package having at least one high temperature solder ball, comprising an alloy of about 95.5% tin, about 4% silver, and about 0.5% copper, attached to at least one microelectronic package bond pad.

22. The method of claim 19, wherein disposing a low temperature solder material on the at least one microelectronic substrate bond pad comprises disposing a low temperature solder material, comprising a tin/bismuth/copper/nickel alloy, on the at least one microelectronic substrate bond pad.

23. The method of claim 13, wherein disposing a low temperature solder material on the at least one microelectronic substrate bond pad comprises disposing a low temperature solder material, comprising a tin/bismuth/copper/antimony alloy, on the at least one microelectronic substrate bond pad.

24. A method of fabricating a microelectronic structure, comprising:
forming a microelectronic package having at least one microelectronic package bond pad;
disposing a low temperature solder material on the at least one microelectronic package bond pad;
attaching at least one high temperature solder ball to the low temperature solder material and then reflowing to form at least one hybrid solder structure;
forming a microelectronic substrate having at least one microelectronic substrate bond pad; and
attaching the microelectronic package to the microelectronic substrate by reflowing the at least one hybrid solder structure to form a hybrid solder interconnect extending between the at least one microelectronic package bond pad and the at least one microelectronic substrate bond pad.

25. The method of claim 24, wherein attaching at least one high temperature solder ball to the low temperature solder material comprises attaching at least one high temperature solder ball, comprising a tin/silver/copper alloy, to the low temperature solder material.

26. The method of claim 25, wherein attaching at least one high temperature solder ball, comprising a tin/silver/copper alloy, to the low temperature solder material comprises attaching at least one high temperature solder ball, comprising an alloy of about 95.5% tin, about 4% silver, and about 0.5% copper, to the low temperature solder material.

27. The method of claim 24, wherein disposing a low temperature solder material on the at least one microelectronic package bond pad comprises disposing a low temperature solder material, comprising a tin/bismuth/copper/nickel alloy, on the at least one microelectronic package bond pad.

28. The method of claim 24, wherein disposing a low temperature solder material on the at least one microelectronic package bond pad comprises disposing a low temperature solder material, comprising a tin/bismuth/copper/antimony alloy, on the at least one microelectronic package bond pad.

29. The method of claim 24, wherein attaching at least one high temperature solder ball to the low temperature solder material and then reflowing to form at least one hybrid solder structure comprises attaching at least one high temperature solder ball to the low temperature solder material and then reflowing to form at least one homogenized hybrid solder structure.
